(19) United States
(12) Patent Application Publication
(10) Pub. No.: US 2022/0302359 A1
(43) Pub. Date: Sep. 22, 2022

(54) LIGHT EMITTING DEVICE, SURFACE LIGHT SOURCE DEVICE, AND DISPLAY DEVICE

(71) Applicant: Enplas Corporation, Saitama (JP)

(72) Inventor: Yuki FUJII, Saitama (JP)

(73) Assignee: Enplas Corporation, Saitama (JP)

(21) Appl. No.: 17/695,026

(22) Filed: Mar. 15, 2022

(30) Foreign Application Priority Data
Mar. 19, 2021 (JP) 2021-046030

(51) Int. Cl. H01L 33/60; H01L 27/15

(52) U.S. Cl. CPC H01L 33/60; H01L 27/156

(57) ABSTRACT

A light emitting device according to an embodiment of the present invention includes a plurality of light emitting elements disposed on a substrate, and a light flux controlling member that is for controlling a distribution of light emitted from the plurality of light emitting elements, and disposed on the plurality of light emitting elements. The light emitting element is disposed in such a way that L1 is longer than L2 when the light flux controlling member is viewed in plan view, where the L1 is a length from the center of gravity of the light flux controlling member to the optical axis of the light emitting element, and the L2 is a length from the center of gravity of the light flux controlling member to the central axis of the incidence unit corresponding to this light emitting element.

### CROSS REFERENCE TO RELATED APPLICATIONS

This application claims the benefit of priority of Japanese Patent Application No. 2021-046030 filed on Mar. 19, 2021, the contents of which are incorporated herein by reference in their entirety.

### TECHNICAL FIELD

The present invention relates to a light emitting device, a surface light source device, and a display device.

### BACKGROUND ART

In recent years, a direct surface light source device including a plurality of light emitting elements as a light source is used in transmission image display devices such as liquid crystal displays. A large number of light emitting elements may be disposed to allow light to illuminate a wide range.

Patent Literature (hereinafter, referred to as PTL) 1 discloses a light flux controlling member (microarray lens) suitable for being disposed over a plurality of light emitting elements. A plurality of lenses are connected by a support plate in these microarray lenses, and one microarray lens is disposed above the plurality of light emitting elements (mini LEDs) disposed on a substrate. This configuration eliminates the necessity to dispose lenses individually above corresponding light emitting elements, and improves the handling property at the time of mounting, thereby facilitating the mounting.

### CITATION LIST

### Patent Literature

PTL 1

Chinese Patent Application Publication No. 110208984

### SUMMARY OF INVENTION

### Technical Problem

In a surface light source device including thereon a large number of light emitting devices as described above—each of the light emitting devices includes a plurality of light emitting elements and light flux control members disposed above the light emitting elements, the present inventors have made attempt to increase the distance between the light emitting elements to reduce the number of light emitting elements. In order to reduce the number of light emitting elements, it is considered necessary to expand light from the light emitting element to a wider range by the light flux controlling member.

Specifically, the present inventors have increased the distance between light emitting device 200′ and light emitting device 200′ as illustrated in FIG. 1. It was found that the balance of the amounts of light between the inside of light emitting device 200′ and the outside of light emitting device 200′ became poor, thereby generating luminance unevenness.

An object of the present invention is to provide a light emitting device capable of preventing the generation of luminance unevenness even if the distance between the light emitting devices is increased. Another object of the present invention is to provide a surface light source device and a display device which include the light emitting device.

### Solution to Problem

A light emitting device of the present invention includes: a plurality of light emitting elements disposed on or above a substrate; and light flux controlling member disposed on or above the plurality of light emitting elements, the light flux controlling member being for controlling a distribution of light emitted from the plurality of light emitting elements, in which the light flux controlling member includes a plurality of incidence units for allowing incidence of the light emitted from the plurality of light emitting elements, respectively, and an emission unit disposed between the plurality of incidence units in a direction along the substrate, the emission unit allowing emission of the light incident on the plurality of incidence units while guiding the light; the plurality of incidence units each include an incidence surface disposed on a back side of the light flux controlling member, the incidence surface allowing incidence of the light emitted from the light emitting element, and a reflection surface disposed on a front side of the light flux controlling member at a position facing the light emitting element with the incidence surface interposed between the reflection surface and the light emitting element, the reflection surface reflecting the light, incident on the incidence surface, in a lateral direction in such a way that the reflected light travels away from an optical axis of the light emitting element; and each light emitting element is disposed in such a way that L1 is longer than L2 when the light flux controlling member is viewed in plan view, where the L1 is a length of a perpendicular line from a center of gravity of the light flux controlling member to a point on the optical axis of the light emitting element when the perpendicular line is drawn from the center of gravity to the optical axis, and the L2 is a length of a perpendicular line from the center of gravity of the light flux controlling member to a point on a central axis of the incidence unit corresponding to the light emitting element when the perpendicular line is drawn from the center of gravity to the central axis.

A surface light source device of the present invention includes a plurality of above-described light emitting devices and a light diffusion plate that transmits light emitted from the plurality of light emitting devices while diffusing the light.

A display device of the present invention includes the above-described surface light source device and a display member to be illuminated by light emitted from the surface light source device.

### Advantageous Effects of Invention

The present invention can provide a light emitting device capable of preventing the generation of luminance unevenness even if the distance between the light emitting devices is increased.

The present invention can also provide a surface light source device and a display device which include at least one light emitting device described above.

### BRIEF DESCRIPTION OF DRAWINGS

FIG. 1 is a diagram for explaining a state when the distance between light emitting devices is increased;

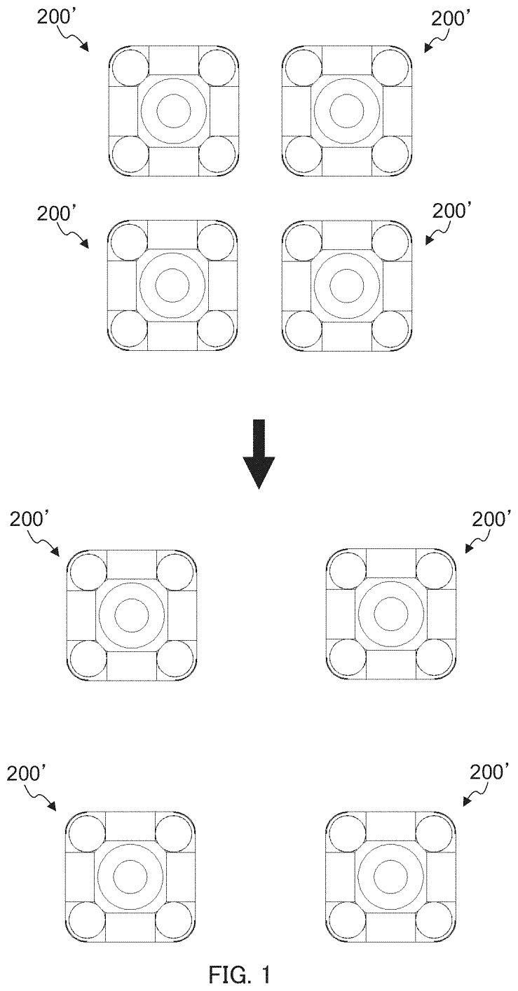

FIGS. 2A and 2B illustrate a surface light source device according to an embodiment;

FIGS. 3A and 3B are cross-sectional views of the surface light source device according to the embodiment;

FIG. 4 is a partially enlarged view of FIG. 3B;

FIGS. 5A to 5E illustrate a light flux controlling member according to the embodiment;

FIG. 6 illustrates a light emitting device according to the embodiment; and

FIG. 7A illustrates the illuminance distribution in a surface light source device according to a comparative example, and FIG. 7B illustrates the illuminance distribution in the surface light source device according to the embodiment.

### DESCRIPTION OF EMBODIMENTS

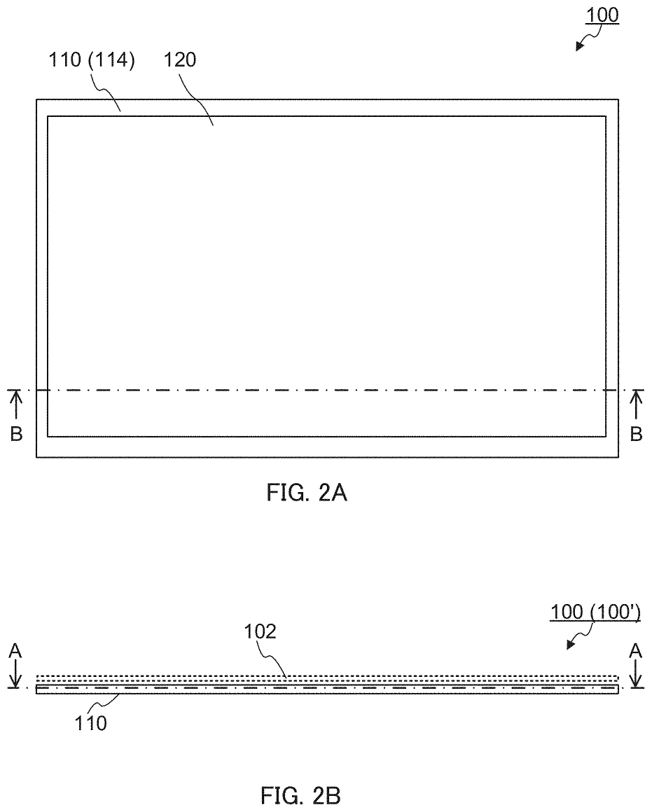

Hereinafter, one or more embodiments of the present invention will be described in detail with reference to the drawings. In the following description, a surface light source device suitable for a backlight of a liquid crystal display device or the like will be described as a typical example of the surface light source device according to the present invention. Such a surface light source device can be used as display device 100′ in combination with display member 102 (for example, a liquid crystal panel) which is to be illuminated by light from the surface light source device (see FIG. 2B).

Configurations of Surface Light Source Device and Light Emitting Device

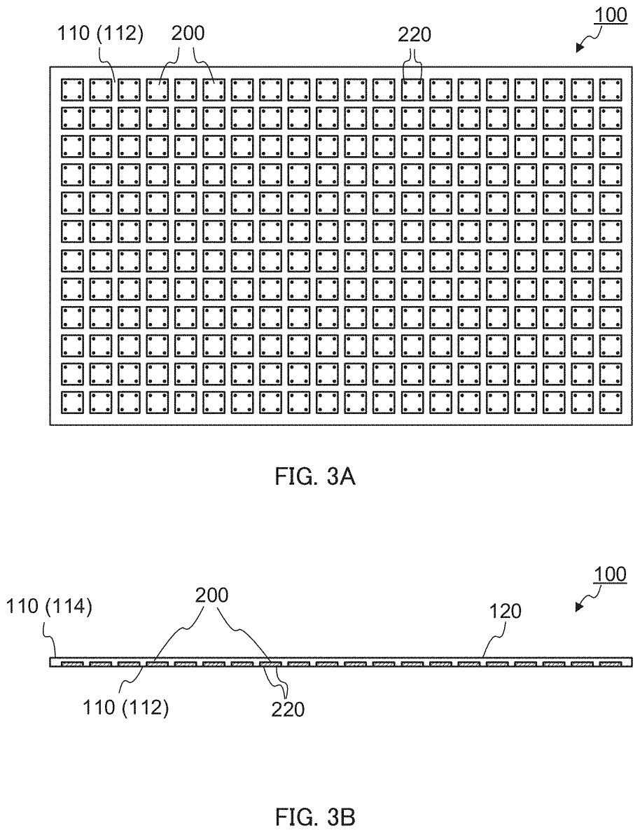

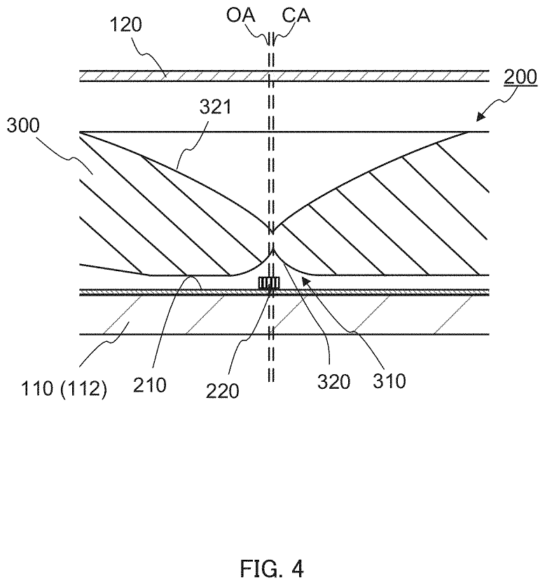

FIGS. 2A and 2B illustrate a configuration of surface light source device 100 according to the embodiment of the present invention. FIG. 2A is a plan view, and FIG. 2B is a front view. FIG. 3A is a cross-sectional view taken along line A-A of FIG. 2B, and FIG. 3B is a cross-sectional view taken along line B-B of FIG. 2A. FIG. 4 is a partially enlarged cross-sectional view illustrating an enlarged part of FIG. 3B.

As illustrated in FIGS. 2A to 3B, surface light source device 100 according to the present embodiment includes casing 110, plurality of light emitting devices 200, and light diffusion plate 120. The plurality of light emitting devices 200 are disposed in a grid pattern (in a matrix) on bottom plate 112 of casing 110. The inner surface of bottom plate 112 functions as a diffusive reflection surface. Top plate 114 of casing 110 is provided with an opening. Light diffusion plate 120 is disposed to close the opening, and functions as a light emitting surface. The light emitting surface may have any size which is, for example, about 400 mm×about 700 mm.

As illustrated in FIG. 4, light emitting device 200 is fixed on substrate 210. Substrate 210 is fixed at a predetermined position on bottom plate 112 of casing 110. Each light emitting device 200 includes plurality of light emitting elements 220 and light flux controlling member 300.

Light emitting element 220 is a light source of surface light source device 100 and is mounted on substrate 210. In the present embodiment, plurality of light emitting elements 220 are disposed in a grid pattern (in a matrix). In addition, in the present embodiment, the pitch at which light emitting elements 220 of corresponding light emitting devices 200 are disposed is longer than the pitch at which light emitting elements 220 are disposed inside light emitting device 200. Light emitting element 220 is, for example, a light emitting diode (LED). Light emitting element 220 may be of any type, and, for example, light emitting element 220 (for example, COB type light emitting diode) which emits light from the top surface and side surface(s) is suitably used in light emitting device 200 according to the embodiment of the present invention. The color of the light emitting element 220 may be any color, such as white, blue, and RGB. The size of the light emitting element 220 is not limited, and is preferably 0.1 mm to 0.6 mm, more preferably 0.1 mm to 0.3 mm.

Light flux controlling member 300 is an optical member for controlling the distribution of light emitted from plurality of light emitting elements 220, and is fixed on substrate 210. In the present embodiment, light flux controlling member 300 is configured to control the distribution of light emitted from four light emitting elements 220. Light flux controlling member 300 includes a plurality of incidence units 310. As described below, each incidence unit 310 includes incidence surface 320 that allows thereon incidence of light emitted from light emitting element 220, and first reflection surface 321 that reflects the light incident on incidence surface 320 toward emission unit 330. In light flux controlling member 300 according to the present embodiment, incidence unit 310 (incidence surface 320 and first reflection surface 321) of light flux controlling member 300 is rotationally symmetric. The rotation axis of incidence unit 310 is referred to as the “central axis of incidence unit 310.” In addition, “optical axis OA of light emitting element 220” means a central light beam of a stereoscopic emission light flux from light emitting element 220. A gap may or may not be formed between substrate 210 with light emitting element 220 mounted thereon and the back surface of light flux controlling member 300 to release the heat generated from light emitting element 220 to the outside.

Light flux controlling member 300 is formed by integral molding. The material of light flux controlling member 300 may be any material that allows light with a desired wavelength to pass therethrough. The material of light flux controlling member 300 is, for example, an optically transparent resin such as polymethylmethacrylate (PMMA), polycarbonate (PC), or an epoxy resin (EP), or glass. The configuration of the light flux controlling member will be described below.

Light diffusion plate 120 is a plate-shaped member having a light diffusing property, and transmits light emitted from light emitting device 200 while diffusing the light. Normally, the size of light diffusion plate 120 is substantially the same as that of the display member such as a liquid crystal panel. Light diffusion plate 120 is formed of, for example, an optically transparent resin such as polymethylmethacrylate (PMMA), polycarbonate (PC), polystyrene (PS), or styrene-methylmethacrylate copolymer resin (MS). In order to provide a light diffusing property, minute irregularities are formed in the surface of light diffusion plate 120, or light diffusing members such as beads are dispersed in light diffusion plate 120.

In surface light source device 100 according to the present embodiment, light emitted from each light emitting element 220 is expanded by light flux controlling member 300 so as to illuminate a wide range of light diffusion plate 120. The light emitted from each light flux controlling member 300 is further diffused by light diffusion plate 120. Surface light source device 100 according to the present embodiment thus can uniformly illuminate a plane-shaped display member (for example, a liquid crystal panel).

Configuration of Light Flux Controlling Member

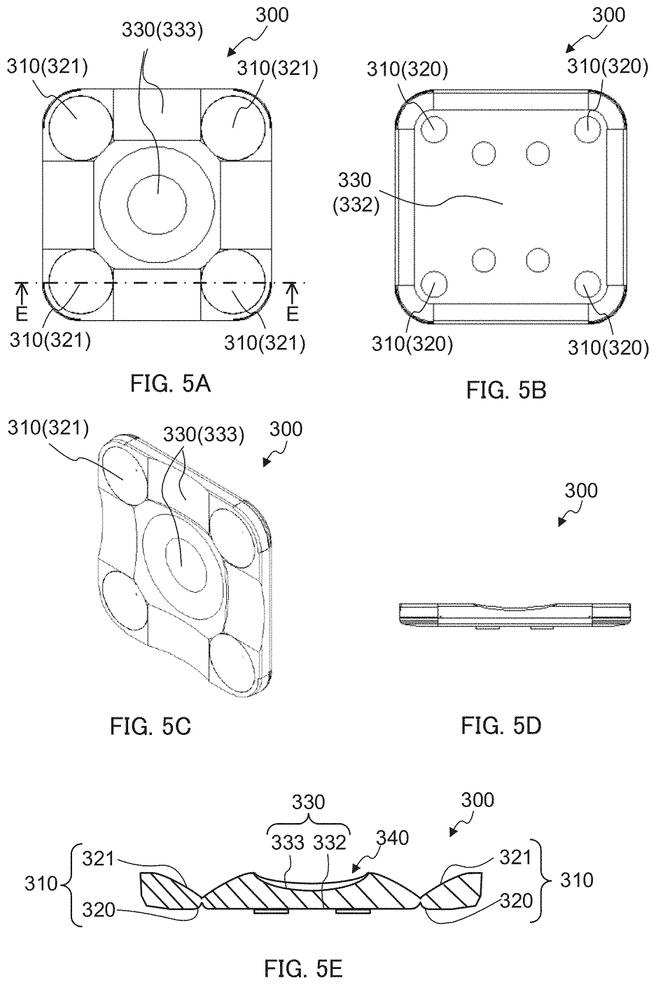

FIG. 5A is a plan view of light flux controlling member 300 of light emitting device 200 according to the present embodiment, FIG. 5B is a bottom view of light flux controlling member 300, FIG. 5C is a perspective view of light flux controlling member 300, FIG. 5D is a side view of light flux controlling member 300, and FIG. 5E is a cross-sectional view taken along line E-E of FIG. 5A. Hereinafter, the configuration of light flux controlling member 300 will be described.

As illustrated in FIG. 5A, light flux controlling member 300 is a substantially plate-shaped member having a rectangular shape with rounded corners in plan view in the present embodiment.

As illustrated in FIGS. 5A to 5E, light flux controlling member 300 according to the present embodiment is for controlling the orientation of light emitted from plurality of light emitting elements 220 disposed on substrate 210. Light flux controlling member 300 includes plurality of incidence units 310 and emission units 330. Plurality of incidence units 310 are disposed in a grid pattern corresponding to the arrangement of light emitting elements 220. Emission unit 330 is disposed between incidence units 310 in the direction along substrate 210.

Each incidence unit 310 allows thereon incidence of light emitted from light emitting element 220. Incidence unit 310 includes incidence surface 320 that allows thereon incidence of light emitted from light emitting element 220 and first reflection surface 321 that reflects the light incident on incidence surface 320 toward emission unit 330.

Incidence surface 320 is disposed on the back side of light flux controlling member 300 and is an inner surface of a recess formed at a position facing light emitting element 220. Incidence surface 320 allows the majority of light emitted from light emitting element 220 to enter light flux controlling member 300, while controlling the travelling direction of the light. Incidence surface 320 intersects optical axis OA of light emitting element 220 and is rotationally symmetric (circular symmetric) about central axis CA. Incidence surface 320 may have any shape which is set in such a way that the light incident on incidence surface 320 is directed toward first reflection surface 321 and emission surface 333. In the present embodiment, incidence surface 320 has a shape such that the distance of the surface from substrate 210 gradually decreases as the distance of the surface from optical axis OA of light emitting element 220 increases.

First reflection surface 321 is disposed on the front side of light flux controlling member 300 at a position facing light emitting element 220 with incidence surface 320 interposed therebetween. First reflection surface 321 reflects light—the light incident on incidence surface 320—in the lateral direction in such a way that the reflected light travels away from optical axis OA of light emitting element 220. More specifically, first reflection surface 321 is preferably configured such that substantially all the light emitted from the center of the light emitting surface of light emitting element 220 is reflected on the first reflecting surface. Herein, the lateral direction does not refer to a direction toward the outer edge of the light flux controlling member, but refers to a direction directed outward in the radial direction 360° about the optical axis.

First reflection surface 321 thus can prevent light incident on the incidence surface 320 from escaping upward, thereby preventing the generation of a bright portion immediately above light emitting element 220. In addition, first reflection surface 321 can also guide the light toward the area between light emitting elements 220, thereby preventing the generation of a dark portion between light emitting elements 220. First reflection surface 321 may have any shape as long as the light incident on incidence surface 320 is laterally reflected. First reflection surface 321 is configured, for example, to be rotationally symmetric (circularly symmetric) about central axis CA of light emitting element 220, and approach the front side (the distance of the surface from substrate 210 increases) as the distance of the surface from optical axis OA of light emitting element 220 increases.

The generatrix from the central portion to the outer peripheral portion of this rotationally symmetric surface is a curved line or a straight line inclined with respect to central axis CA. First reflection surface 321 is a concave surface in a state where the generatrix is rotated by 360° with central axis CA of incidence surface 320 as a rotation axis.

In the present embodiment, incidence surface 320 and first reflection surface 321 are each an inner surface of a recess. The area of the opening edge of the recess forming the first reflecting surface is preferably 0.5 to 2.0 times, more preferably 0.5 to 1.5 times, and particularly preferably 0.5 to 1.3 times, the area of the opening edge of the recess forming the incidence surface, in plan view.

Emission unit 330 emits light incident on plurality of incidence units 310 while guiding the light. A part of the light guided through emission unit 330 reaches the side surface of light flux controlling member 300 and is emitted to the outside. In the present embodiment, when four incidence units 310 are disposed at individual corners of a virtual quadrangle, light flux controlling member 300 includes four emission units 330 disposed at positions corresponding to the four sides of the virtual quadrangle in such a way that each emission unit is disposed along the corresponding side, and one emission unit 330 disposed so as to be surrounded by the virtual quadrangle. As illustrated in FIG. 5E, each emission unit 330 includes second reflection surface 332 which is disposed on the back side of light flux controlling member 300, and reflects light from first reflection surface 321 of incidence unit 310. Emission unit 330 also includes emission surface 333 that is disposed on the front side of light flux controlling member 300 so as to face second reflection surface 332. Emission surface 333 reflects a part of the light from incidence unit 310 and emits another part of the light.

In addition, in the present embodiment, emission unit 330 includes emission promotion part 340 for promoting the emission of light traveling between second reflection surface 332 and emission surface 333. Emission promotion part 340 is disposed in at least one of second reflection surface 332 and emission surface 333.

As illustrated in FIG. 5E, in the present embodiment, emission promotion part 340 is formed at emission surface 333. The distance between emission surface 333 and second reflection surface 332 decreases as the distances of the surfaces from incidence unit 310 increase. Such a configuration allows the light guided from incidence unit 310 to be emitted more readily from emission surface 333 as the distance from incidence unit 310 increases.

Emission surface 333 may have any shape. In the present embodiment, four emission surfaces 333 disposed at positions corresponding to the four sides of the virtual quadrangle are each a concave surface having a curvature in the direction along the corresponding side of the virtual quadrangle and no curvature in the direction perpendicular to this side (see FIGS. 5A to 5E). Emission surface 333 disposed so as to be surrounded by the virtual quadrangle is a concave surface formed by the bottom (located at the top) and a part of the side surface of a truncated cone disposed upside down (see FIG. 5C).

In addition, in the present embodiment, light is emitted toward the space between light emitting devices 200 not only from above-described emission surface 333 but also from the side surface of incidence unit 310 and the side surface of emission unit 330.

Positional Relationship between Light Emitting Element and Incidence Unit

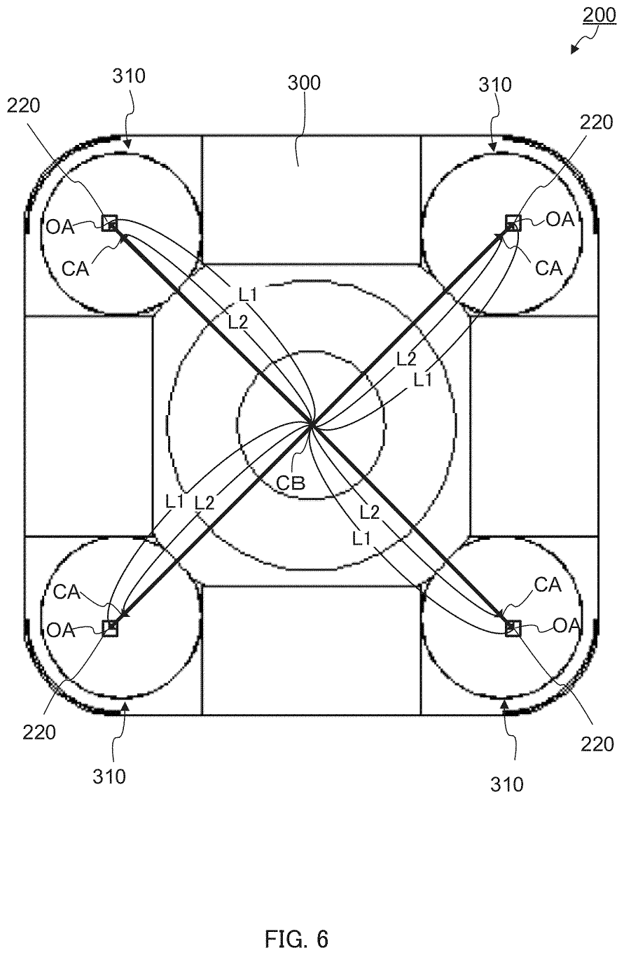

FIG. 6 is a diagram for explaining the positional relationship between light emitting element 220 and incidence unit 310 of light flux controlling member 300 in light emitting device 200. It should be noted that FIG. 6 is for explanation and does not represent an actual scale or the like.

As illustrated in FIG. 6, light emitting element 220 is disposed in light emitting device 200 according to the present embodiment in such a way that L1 is longer than L2 when light flux controlling member 300 is viewed in plan view. In this configuration, the L1 is a length of a perpendicular line from center of gravity CB of light flux controlling member 300 to a point on optical axis OA of light emitting element 220 when the perpendicular line is drawn from center of gravity CB to optical axis OA; and the L2 is a length of a perpendicular line from center of gravity CB of light flux controlling member 300 to a point on central axis CA of incidence unit 310 corresponding to this light emitting element 220 when the perpendicular line is drawn from center of gravity CB to central axis CA. Herein, the central axis of incidence unit 310 is a line connecting the center of incidence surface 320 with the center of the reflection surface (first reflection surface 321). With the above disposition, light emitting element 220 is disposed so as to be slightly offset from the central axis of incidence unit 310 toward the outside of light flux controlling member 300. By disposing light emitting element 220 as described above, increased amount of light from light emitting element 220 is emitted toward the space between light emitting devices 200, and the balance between the amount of light directed toward the area immediately above light emitting device 200 and the amount of light directed toward the space between the light emitting devices 200 is improved, thereby preventing the generation of luminance unevenness on the light emitting surface (light diffusion plate 120). In the present embodiment, L1 is longer than L2 by 71 μm.

When light flux controlling member 300 is viewed in plan view, L1 and L2 may or may not be superposed on each other. In the present embodiment, L1 and L2 are superposed on each other as illustrated in FIG. 6. When L1 and L2 are not superposed on each other, the angle formed by L1 and L2 is preferably small, for example, 5° or less.

In addition, in the present embodiment, light emitting element 220 is disposed in such a way that substantially all the light emitted from the center of the light emitting surface of light emitting element 220 is totally reflected by first reflection surface 321. Disposing light emitting element 220 as described above can prevent the generation of a bright spot immediately above first reflection surface 321 (generation of luminance unevenness), which would be caused by light from light emitting element 220 passing through first reflection surface 321.

Illuminance Distribution

For confirming the effect of light flux controlling member 300 according to the present embodiment, the illuminance distribution on the back surface of light diffusion plate 120 (the surface on the light emitting device 200 side) was measured in surface light source device 100 that includes light emitting device 200 according the present embodiment, and in a surface light source device that includes a light emitting device according to a comparative example.

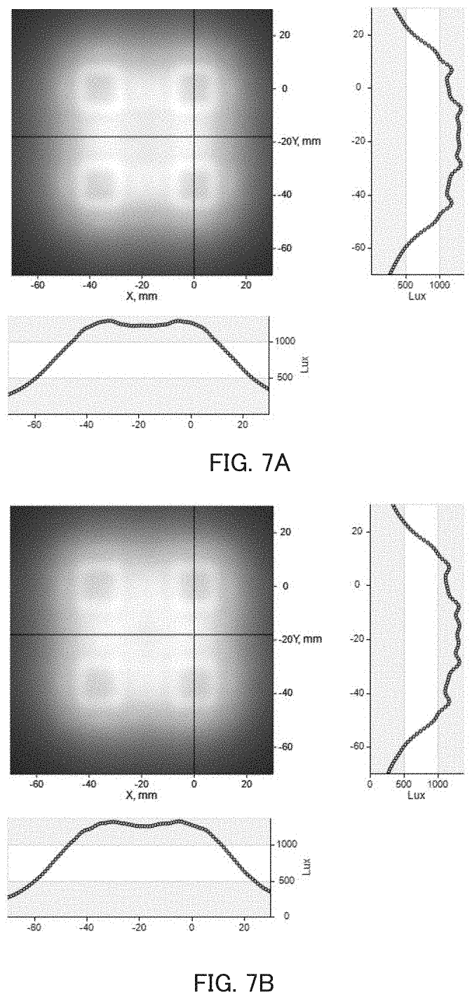

FIG. 7A illustrates the illuminance distribution in the surface light source device according to the comparative example. In the light emitting device of the surface light source device of FIG. 7A, optical axis OA of light emitting element 220 and central axis CA of incidence unit 310 coincide with each other, and the length of L1 is the same as the length of L2 when the device is viewed in plan view. FIG. 7B illustrates the illuminance distribution in surface light source device 100 according to the embodiment. In light emitting device 200 of surface light source device 100 of FIG. 7B, optical axis OA of light emitting element 220 and central axis CA of incidence unit 310 are offset from each other, and the L1 is longer than the L2 when the device is viewed in plan view, as illustrated in FIG. 6.

FIGS. 7A and 7B each show four light emitting devices 200 disposed in a grid pattern among a large number of light emitting devices 200 disposed in the surface light source device. FIGS. 7A and 7B each show the illuminance distribution on light diffusion plate 120 when four light emitting elements 220 individually included in four light emitting devices 200 were turned on. In each of FIGS. 7A and 7B, the lower graph shows the illuminance distribution in the horizontal direction between upper two light emitting devices 200 and lower two light emitting devices 200, and the right side graph shows the illuminance distribution in the vertical direction passing between two light emitting elements 220 disposed in the horizontal direction in each of light emitting devices 200 disposed on the right side.

The comparison between the graphs in FIGS. 7A and 7B shows that the surface light source device according to the comparative example has a larger difference in illuminance between the area immediately above light emitting device 200 and the area between light emitting devices 200, and meanwhile surface light source device 100 according to the example has a smaller difference. The comparison also shows that the areas between the four light emitting devices disposed in a grid pattern are dark in the surface light source device according to the comparative example, but the corresponding areas are relatively bright in surface light source device 100 according to the present embodiment.

Effects

The distance between light emitting devices 200 can be increased while preventing the generation of luminance unevenness in light emitting device 200 of the present embodiment because of the excellent balance of the amounts of light between the inside of light emitting device 200 and the outside of light emitting device 200.

### Industrial Applicability

The light emitting device and the surface light source device of the present invention may be applied to, for example, a backlight of a liquid crystal display device and general-purpose lighting.

### REFERENCE SIGNS LIST

100 Surface light source device
100′ Display device
102 Display member
110 Casing
112 Bottom plate
114 Top plate
120 Light diffusion plate
200, 200′ Light emitting device
210 Substrate
220 Light emitting element
300 Light flux controlling member
310 Incidence unit
320 Incidence surface
321 First reflection surface
330 Emission unit
332 Second reflection surface
333 Emission surface
340 Emission promotion part
CA Central axis
OA Optical axis
CB Center of gravity

1. A light emitting device comprising:
a plurality of light emitting elements disposed on or above a substrate; and
a light flux controlling member disposed on or above the plurality of light emitting elements, the light flux controlling member being for controlling a distribution of light emitted from the plurality of light emitting elements,
wherein the light flux controlling member includes
a plurality of incidence units for allowing incidence of the light emitted from the plurality of light emitting elements, respectively, and
an emission unit disposed between the plurality of incidence units in a direction along the substrate, the emission unit allowing emission of the light incident on the plurality of incidence units while guiding the light,
wherein the plurality of incidence units each include
an incidence surface disposed on a back side of the light flux controlling member, the incidence surface allowing incidence of the light emitted from the light emitting element, and
a reflection surface disposed on a front side of the light flux controlling member at a position facing the light emitting element with the incidence surface interposed between the reflection surface and the light emitting element, the reflection surface reflecting the light, incident on the incidence surface, in a lateral direction in such a way that the reflected light travels away from an optical axis of the light emitting element, and
wherein the light emitting element is disposed in such a way that L1 is longer than L2 when the light flux controlling member is viewed in plan view, where
the L1 is a length of a perpendicular line from a center of gravity of the light flux controlling member to a point on the optical axis of the light emitting element when the perpendicular line is drawn from the center of gravity to the optical axis, and
the L2 is a length of a perpendicular line from the center of gravity of the light flux controlling member to a point on a central axis of the incidence unit corresponding to the light emitting element when the perpendicular line is drawn from the center of gravity to the central axis.

2. The light emitting device according to claim 1, wherein the L1 and the L2 are superposed on each other when the light flux controlling member is viewed in plan view.

3. The light emitting device according to claim 1, wherein the light emitting element is disposed in such a way that substantially all of light emitted from a center of a light emitting surface of the light emitting element is totally reflected by the reflection surface.

4. A surface light source device, comprising:
a plurality of the light emitting devices according to claim 1; and
a light diffusion plate that transmits light emitted from the plurality of light emitting devices while diffusing the light.

5. A display device, comprising:
the surface light source device according to claim 4; and
a display member to be illuminated by light emitted from the surface light source device.
